(19) United States
(12) Patent Application Publication
(10) Pub. No.: US 2024/0407150 A1
(43) Pub. Date: Dec. 5, 2024

(54) METHODS OF MANUFACTURING SEMICONDUCTOR DEVICE

(71) Applicant: SAMSUNG ELECTRONICS CO., LTD., Suwon-si (KR)

(72) Inventors: Sukhwa Jang, Suwon-si (KR); Kanguk Kim, Seoul (KR); Hyunsuk Noh, Suwon-si (KR); Yeongshin Park, Seoul (KR); Sangkyu Sun, Seoul (KR); Sunyoung Lee, Yongin-si (KR); Sohyang Lee, Seoul (KR); Hongjun Lee, Suwon-si (KR); Hosun Jung, Gimpo-si (KR); Jeongmin Jin, Suwon-si (KR); Jeonghee Choi, Seoul (KR); Jinseo Choi, Hwaseong-si (KR); Cera Hong, Hwaseong-si (KR)

(21) Appl. No.: 18/737,605

(22) Filed: Jun. 7, 2024

Related U.S. Application Data
(63) Continuation of application No. 17/398,136, filed on Aug. 10, 2021, now Pat. No. 12,022,645.

(30) Foreign Application Priority Data
Oct. 20, 2020 (KR) 10-2020-0136089

(51) Int. Cl. H10B 12/00

(52) U.S. Cl. CPC H10B 12/0335; H10B 12/053; H10B 12/09; H10B 12/315; H10B 12/34; H10B 12/50

(57) ABSTRACT

A method of manufacturing a semiconductor device includes forming a lower structure including a plurality of transistors, forming a conductive layer on the lower structure, forming first preliminary pad mask patterns and wiring mask patterns on the conductive layer, forming pad mask patterns by patterning the first preliminary pad mask patterns while protecting the wiring mask patterns, and etching the conductive layer using the pad mask patterns and the wiring mask patterns as an etching mask to form pad patterns and wiring patterns.

### CROSS-REFERENCE TO RELATED APPLICATION

This application is a continuation of U.S. application Ser. No. 17/398,136, filed Aug. 10, 2021, which claims priority to Korean Patent Application No. 10-2020-0136089 filed on Oct. 20, 2020, in the Korean Intellectual Property Office, and entitled: “Methods of Manufacturing Semiconductor Device,” is incorporated by reference herein in its entirety.

### BACKGROUND

### 1. Field

Embodiments relate to a semiconductor device and a method of manufacturing a semiconductor device.

### 2. Description of the Related Art

Research is being conducted to reduce the size of elements constituting semiconductor devices and to improve performance thereof. For example, in dynamic random-access memory (DRAM) devices, research is being conducted to reliably and stably form elements having a reduced size.

### SUMMARY

According to example embodiments, a method of manufacturing a semiconductor device includes forming a lower structure including a plurality of transistors; forming a conductive layer on the lower structure; forming first preliminary pad mask patterns and wiring mask patterns on the conductive layer; forming pad mask patterns by patterning the first preliminary pad mask patterns while protecting the wiring mask patterns; and etching the conductive layer using an etching process using the pad mask patterns and the wiring mask patterns as an etching mask to form pad patterns and wiring patterns.

According to example embodiments, a method of manufacturing a semiconductor device includes forming a lower structure including first transistors and second transistors; forming a conductive layer on the lower structure; forming a first mask layer on the conductive layer; patterning the first mask layer in a patterning process using a first photolithography process using extreme ultraviolet (EUV) light as a light source, to form first preliminary pad mask patterns and wiring mask patterns; forming second preliminary pad mask patterns and a wiring mask protective layer using a multi-patterning technique; etching the first preliminary pad mask patterns using an etching process using the second preliminary pad mask patterns and the wiring mask protective layer as an etching mask, to form pad mask patterns while protecting the wiring mask patterns; and etching the conductive layer using an etching process using the pad mask patterns and the wiring mask patterns as an etching mask, to form pad patterns and wiring patterns. The pad patterns are electrically connected to the first transistors, at least some of the wiring patterns are electrically connected to the second transistors. The multi-patterning technique includes performing, at least once, a second photolithography process using deep ultraviolet (DUV) light having a wavelength longer than a wavelength of extreme ultraviolet (EUV) light, as a light source, and the multi-patterning technique further includes performing a patterning process once or a plurality of times, the pattern process including performing a deposition process and an etching process without a photolithography process.

According to example embodiments, a method of manufacturing a semiconductor device includes forming a conductive layer on a semiconductor substrate, and patterning the conductive layer to form pad patterns and wiring patterns. The patterning the conductive layer includes respectively performing a first patterning process including a first photolithography process using extreme ultraviolet (EUV) light as a light source, and performing a second patterning process including a second photolithography process of using deep ultraviolet (DUV) light having a wavelength longer than a wavelength of the extreme ultraviolet (EUV) light, as a light source. The second patterning process is performed after the first patterning process is performed. The pad patterns are formed after performing both the first patterning process and the second patterning process. The wiring patterns are formed by the first patterning process before performing the second patterning process.

### BRIEF DESCRIPTION OF DRAWINGS

Features will become apparent to those of skill in the art by describing in detail exemplary embodiments with reference to the attached drawings, in which:

FIG. 1A is a schematic plan view of a semiconductor device according to an example embodiment;

FIG. 1B is a plan view illustrating some components of FIG. 1A;

FIG. 2A is a schematic cross-sectional view along lines I-I′ and II-II′ of FIG. 1A;

FIG. 2B is a schematic cross-sectional view along line III-III′ of FIG. 1A;

FIG. 3 is a schematic plan view of another example of a semiconductor device according to an example embodiment;

FIG. 4A is a schematic cross-sectional view along lines IV-IV′ and V-V′ of FIG. 3;

FIG. 4B is a schematic cross-sectional view along line VI-VI′ of FIG. 3;

FIGS. 5A and 5B are process flow diagrams of a method of manufacturing a semiconductor device according to an example embodiment; and

FIGS. 6A, 6B, 7, 8A, 8B, 9A, 9B, 10A, 10B, 11A, 11B, 12A, 12B, 13A, 13B, 14A, 14B, 15, 16, 17A, 17B, 18, 19A, and 19B are cross-sectional views of stages in a method of manufacturing a semiconductor device according to an example embodiment.

### DETAILED DESCRIPTION

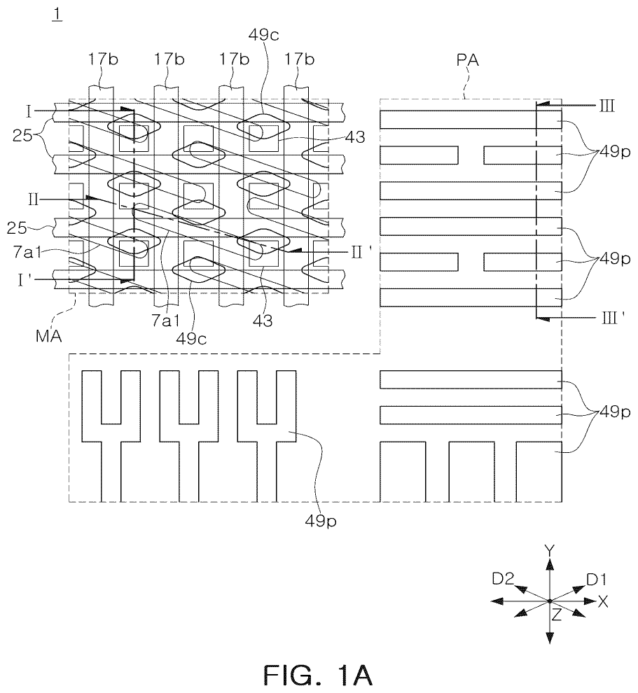

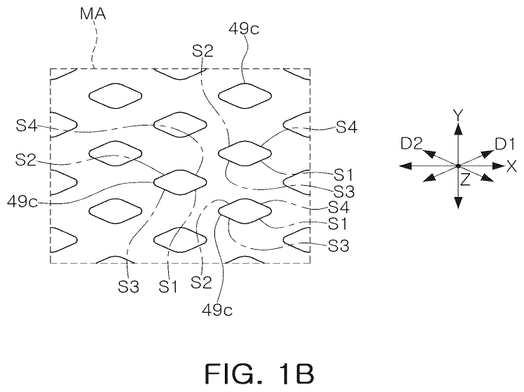

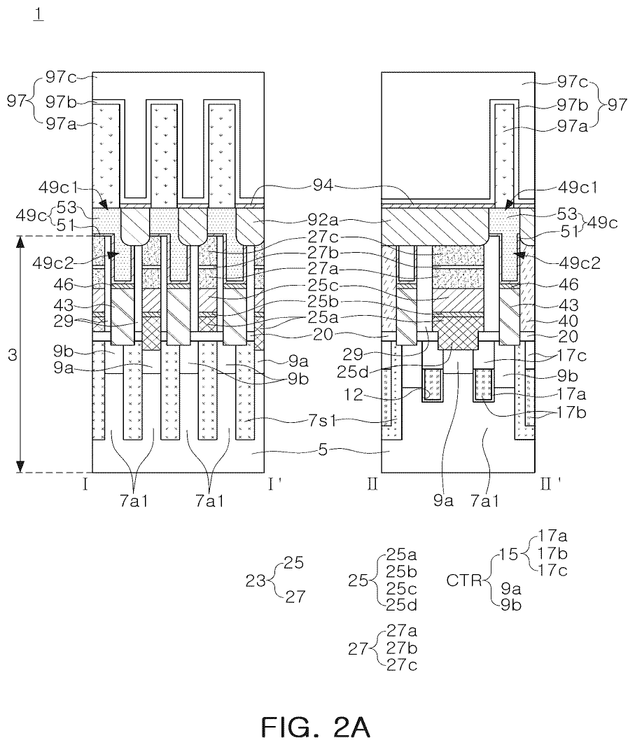

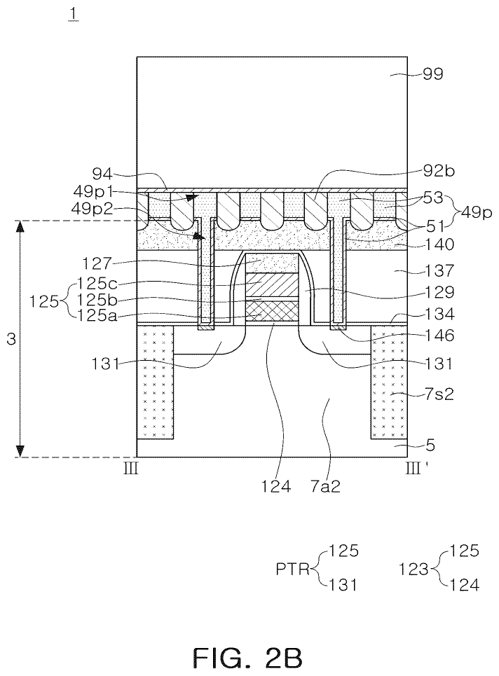

FIG. 1A is a plan view schematically illustrating an example of a semiconductor device according to an example embodiment, FIG. 1B is a plan view illustrating pad patterns 49c of FIG. 1A, FIG. 2A is a cross-sectional view along lines I-I′ and II-II′ of FIG. 1A, and FIG. 2B is a cross-sectional view along line III-III′ of FIG. 1A.

Referring to FIGS. 1A, 1B, 2A and 2B, a semiconductor device 1 according to an example embodiment may include a lower structure 3 having a plurality of transistors CTR and PTR, pad patterns 49c and wiring patterns 49p on the lower structure 3, and a data storage structure 97 electrically connected to the pad patterns 49c, on the lower structure 3.

In example embodiments, the lower structure 3 may include a semiconductor substrate 5 having a first area MA and a second area PA, first active regions 7al on the semiconductor substrate 5 of the first area MA, second active regions 7a2 on the semiconductor substrate 5 of the second area PA, a first device isolation region 7s1 on side surfaces of the first active regions 7a1, and a second device isolation region 7s2 on side surfaces of the second active regions 7a2.

Hereinafter, for convenience of description, a description will be given centering on one first active region 7al and one second active region 7a2. In addition, hereinafter, even in the case in which a description is focused on one component, it may be understood that the one component may be disposed in plural.

In example embodiments, the lower structure 3 may further include one or a plurality of gate trenches 12 crossing the first active region 7al and extending to the first device isolation region 7s1, first gate structures 15 disposed in the gate trenches 12, and a first impurity region 9a and a second impurity region 9b disposed in the first active region 7al adjacent to side surfaces of the first gate structures 15. Each of the first gate structures 15 may include a first gate electrode 17b, a first gate dielectric 17a between the first gate electrode 17b and the first active region 7al, and a first gate capping layer 17c on the first gate electrode 17b. The first gate electrode 17b may be formed of a conductive material, and the first gate capping layer 17c may be formed of an insulating material. For example, the first gate electrode 17b may include doped polysilicon, metal, conductive metal nitride, conductive metal silicide, conductive metal oxide, graphene, carbon nanotubes, or combinations thereof. For example, the first gate electrode 17b may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, carbon nanotubes, or combinations thereof, but the material thereof is not limited thereto. The first gate electrode 17b may include a single layer or multiple layers of the aforementioned materials.

Any one of the first gate structures 15 and the first and second impurity regions 9a and 9b disposed on both sides of the first gate structure 15 may constitute a first transistor CTR. In this case, the first and second impurity regions 9a and 9b may be first source/drain regions.

In example embodiments, the lower structure 3 may further include a second gate structure 123 disposed on the second active region 7a2, a peripheral gate capping layer 127 on the second gate structure 123, and second source/drain regions 131 disposed in the second active region 7a2 on both sides of the second gate structure 123. The second gate structure 123 may include a second gate dielectric 124 and a second gate electrode 125 on the second gate dielectric 124. The second gate electrode 125 may include a first electrode material layer 125a, a second electrode material layer 125b, and a third electrode material layer 125c sequentially stacked. For example, the first electrode material layer 125a may include doped silicon, e.g., polysilicon having N-type conductivity or polysilicon having P-type conductivity, the second electrode material layer 125b may include a metal-semiconductor compound, e.g., tungsten silicide, and the third electrode material layer 125c may include a metal, e.g., tungsten. The second gate electrode 125 and the second source/drain regions 131 may constitute a second transistor PTR. The peripheral gate capping layer 127 may be formed of an insulating material, e.g., silicon nitride.

In example embodiments, the first area MA may be a memory cell area in which memory cells storing information are disposed, and the second area PA may be a peripheral area or a peripheral circuit area disposed in an area adjacent to the first area MA. Hereinafter, the first area MA will be referred to as a memory cell area, and the second area PA will be referred to as a peripheral circuit area in the description below.

In example embodiments, the first active region 7al may be a cell active region, and the second active region 7a2 may be a peripheral active region. Hereinafter, the first active region 7al will be referred to as a cell active region, and the second active region 7a2 will be referred to as a peripheral active region.

In example embodiments, the first transistor CTR may be a cell transistor or a cell switching device, and the second transistor PTR may be a peripheral transistor or a peripheral circuit transistor. Hereinafter, the first transistor CTR will be referred to as a cell transistor, and the second transistor PTR will be referred to as a peripheral transistor. The first gate electrode 17b of the cell transistor CTR may be a cell gate electrode or a word line, and the second gate electrode 125 of the peripheral transistor PTR may be a peripheral gate electrode.

In example embodiments, the lower structure 3 may further include a buffer insulating layer 20 formed on the cell active region 7al and the first device isolation region 7s1.

In example embodiments, the lower structure 3 may further include a bit line structure 23 and a contact plug 43. The bit line structure 23 may include a bit line 25 and a bit line capping layer 27 that are sequentially stacked. The bit line 25 may be formed of a conductive material. The bit line 25 may include a first bit line material layer 25a, a second bit line material layer 25b, and a third bit line material layer 25c sequentially stacked. For example, the first bit line material layer 25a may include doped silicon, e.g., polysilicon having N-type conductivity, the second bit line material layer 25b may include a metal-semiconductor compound, e.g., tungsten silicide, and the third bit line material layer 25c may include a metal, e.g., tungsten. The bit line capping layer 27 may include a first bit line capping layer 27a, a second bit line capping layer 27b, and a third bit line capping layer 27c sequentially stacked. The bit line capping layer 27 may be formed of an insulating material. Each of the first to third bit line capping layers 27a, 27b and 27c may be formed of silicon nitride or a silicon nitride-based insulating material.

In example embodiments, the bit line 25 may further include a bit line contact portion 25d extending downwardly from the first bit line material layer 25a and electrically connected to the first impurity region 9a. The bit line 25 may be formed on the buffer insulating layer 20, and the bit line contact portion 25d of the bit line 25 may penetrate through the buffer insulating layer 20 to contact the first impurity region 9a.

In example embodiments, the contact plug 43 may penetrate through the buffer insulating layer 20 and may contact the second impurity region 9b. The contact plug 43 may include doped silicon, e.g., polysilicon having N-type conductivity.

In example embodiments, the lower structure 3 may further include a bit line spacer 29 that may contact side surfaces of the bit line structure 23 and may be formed of an insulating material, and a peripheral gate spacer 129 that may be in contact with side surfaces of the second gate structure 123 and may be formed of an insulating material.

In example embodiments, the lower structure 3 may further include a partition wall insulating pattern 40 contacting the contact plug 43, between a pair of the bit lines 25 adjacent to and parallel to each other. For example, between a pair of the bit lines 25 that are adjacent and parallel to each other, the contact plug 43 may be disposed in plural, and the partition wall insulating pattern 40 may be disposed between the plurality of contact plugs 43.

In example embodiments, the lower structure 3 may further include an insulating liner 134 covering the peripheral active region 7a2 and the second device isolation region 7s2, and covering the surface of the peripheral gate spacer 129 and the upper surface of the second gate structure 123. The lower structure 3 may further include a first interlayer insulating layer 137 on the insulating liner 134, and a second interlayer insulating layer 140 on the first interlayer insulating layer 137. In an example, a portion of the insulating liner 134 positioned on the upper surface of the second gate structure 123 may contact the second interlayer insulating layer 140. The second gate structure 123 may be a peripheral gate structure.

In example embodiments, the first interlayer insulating layer 137 may be formed of a material different from that of the insulating liner 134 and the second interlayer insulating layer 140. For example, the first interlayer insulating layer 137 may be formed of silicon oxide or a silicon oxide-based insulating material, and the insulating liner 134 and the second interlayer insulating layer 140 may be formed of silicon nitride or a silicon nitride-based insulating material.

The pad patterns 49c may be disposed on the memory cell area MA of the semiconductor substrate 5, and the wiring patterns 49p may be disposed on the peripheral circuit area PA of the semiconductor substrate 5.

The pad patterns 49c and the wiring patterns 49p may be formed of the same conductive material. For example, each of the pad patterns 49c and the wiring patterns 49p may include a first conductive material layer 51, and a second conductive material layer 53 on the first conductive material layer 51. For example, the first conductive material layer 51 may include a metal nitride, e.g., titanium nitride, and the second conductive material layer 53 may include a metal, e.g., tungsten.

In example embodiments, each of the pad patterns 49c may include a pad portion 49cl on the lower structure 3, and a first plug portion 43c2 extending from the pad portion 49cl into the lower structure 3 and electrically connected to the contact plug 43. Accordingly, the pad patterns 49c may be electrically connected to the cell transistors CTR through the contact plugs 43.

In example embodiments, at least one of the wiring patterns 49p may include a wiring portion 49p1 on the lower structure 3, and a second plug portion 43p2 extending from the wiring portion 49p1 into the lower structure 3 and electrically connected to the peripheral transistor PTR. Accordingly, at least some of the wiring patterns 49p may be electrically connected to the peripheral transistor PTR.

In example embodiments, the lower structure 3 may further include a first metal-semiconductor compound layer 46 electrically connecting the contact plug 43 and the first plug portion 43c2, between the contact plug 43 and the first plug portion 43c2, and a second metal-semiconductor compound layer 146 electrically connecting the second source/drain regions 131 and the second plug portion 43p2, between the second source/drain region 131 and the second plug portion 43p2.

In example embodiments, as illustrated in FIG. 1A, when viewed in a plan view, the bit lines 25 may have a line shape extending in a first horizontal direction X, and the first gate electrodes 17b, e.g., the word lines, may have a line shape extending in a second horizontal direction Y perpendicular to the first horizontal direction X. As illustrated in FIG. 1B, each of the pad patterns 49c may have a first side S1 and a second side S2 opposing each other and parallel to each other, and a third side S3 and a fourth side S4 opposing each other and parallel to each other. Each of the pad patterns 49c may have the first to fourth sides S1, S2, S3 and S4, and may have a rounded shape in a region in which the first to fourth sides S1, S2, S3 and S4 meet each other. For example, when viewed in a plan view, each of the pad patterns 49c may have edges such as the first to fourth sides S1, S2, S3 and S4, and may have a rounded shape in portions in which the edges S1, S2, S3 and S4 are adjacent to each other. In example embodiments, each of the pad patterns 49c may have an oval shape, a circle shape, or a quadrangular shape in which vertex portions are rounded.

In example embodiments, when viewed in a plan view, in each of the pad patterns 49c, the first and second sides S1 and S2 may have a line shape extending in a first diagonal direction D1 that forms an acute angle with respect to the first horizontal direction X, and the third and fourth sides S3 and S4 may have a line shape extending in a second diagonal direction D2 that forms an obtuse angle with respect to the first horizontal direction X.

In example embodiments, when viewed in a plan view, among the pad patterns 49c, in the pad patterns sequentially arranged in the first diagonal direction D1, the first sides S1 may be aligned in the first diagonal direction D1, and the second sides S2 may be aligned in the first diagonal direction D1. In example embodiments, in a plan view, among the pad patterns 49c, in the pad patterns sequentially arranged in the second diagonal direction D2, the third sides S3 may be aligned in the second diagonal direction D2, and the fourth sides S4 may be aligned in the second diagonal direction D2.

The semiconductor device 1 according to an example embodiment may further include first insulating patterns 92a filling between the pad patterns 49c and second insulating patterns 92b filling between the wiring patterns 49p, on the lower structure 3. The first insulating patterns 92a may fill between the pad portions 49cl of the pad patterns 49c and extend into the lower structure 3, and the second insulating patterns 92b may fill between the wiring portions 49p1 of the wiring patterns 49p and extend into the lower structure 3. A lower surface of each of the first and second insulating patterns 92a and 92b may be disposed on a lower level than a lower surface of each of the pad portions 49cl and the wiring portions 49p1, e.g., a distance between a bottom of the semiconductor substrate 5 and the lower surface of each of the first and second insulating patterns 92a and 92b may be smaller than a distance between the bottom of the semiconductor substrate 5 and a corresponding one of the lower surfaces of the pad portions 49cl and the wiring portions 49p1.

In example embodiments, the data storage structure 97 may be a capacitor that stores information in a DRAM device. For example, the data storage structure 97 may include first electrodes 97a electrically connected to the pad patterns 49c, on the pad patterns 49c, a second electrode 97c covering the first electrodes 97a, and a dielectric layer 97b disposed between the first electrodes 97a and the second electrode 97c. The dielectric layer 97b may be a dielectric layer of a capacitor that stores information in a DRAM device.

In another embodiment, the data storage structure 97 may be a data storage structure capable of storing information in a nonvolatile memory device, e.g., a magnetoresistive random-access memory (MRAM) device or a variable resistance memory device.

The semiconductor device 1 according to an example embodiment may further include an etch stop insulating layer 94 on the first and second insulating patterns 92a and 92b and the wiring patterns 49p.

The semiconductor device 1 according to an example embodiment may further include an upper insulating layer 99 covering the wiring patterns 49p, on the etch stop insulating layer 94 on the second area PA of the semiconductor substrate 5.

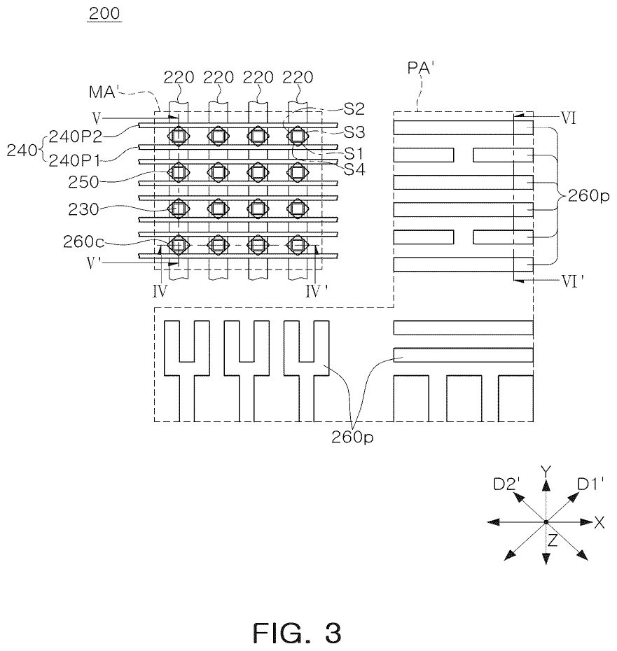

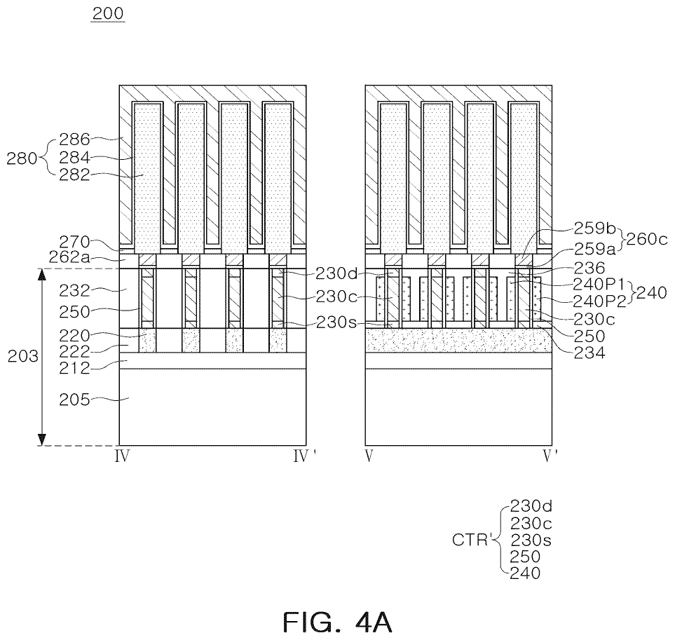

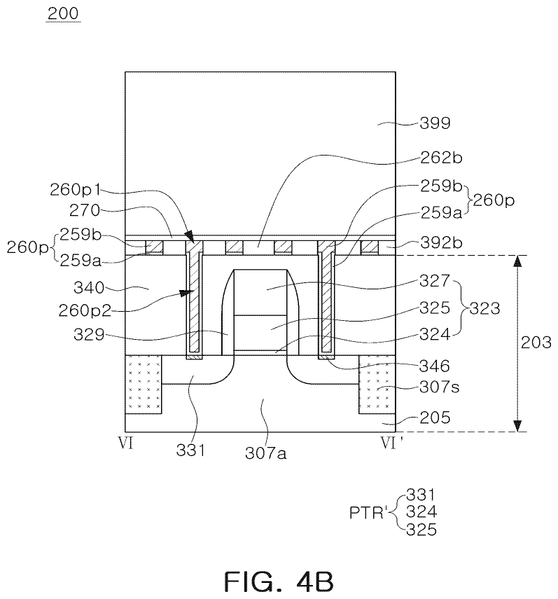

Next, another example of a semiconductor device according to an example embodiment will be described with reference to FIGS. 3, 4A, and 4B. FIG. 3 is a schematic plan view illustrating another example of a semiconductor device according to an example embodiment. FIG. 4A is a cross-sectional view along lines IV-IV′ and V-V′ of FIG. 3, and FIG. 4B is a cross-sectional view along line VI-VI′ of FIG. 3.

Referring to FIGS. 3, 4A and 4B, a semiconductor device 200 according to an example embodiment may include a lower structure 203, pad patterns 260c, wiring patterns 260p, and a data storage structure 280. The semiconductor device 200 according to an example embodiment may further include first insulating patterns 262a filling between the pad patterns 260c, and second insulating patterns 262b filling between the wiring patterns 260p.

The lower structure 203 may include a semiconductor substrate 205 including a memory cell area MA′ and a peripheral circuit area PA′. The lower structure 203 may further include a plurality of first conductive lines 220, channel layers 230c, lower source/drain regions 230s, upper source/drain regions 230d, cell gate electrodes 240, and cell gate dielectrics 250, disposed on the memory cell area MA′.

The channel layers 230c, the lower source/drain regions 230s, the upper source/drain regions 230d, and the cell gate electrodes 240 may form vertical channel transistors CTR′. In this case, the vertical channel transistors CTR′ may also be referred to as cell transistors. The vertical channel transistor CTR′ may refer to a structure in which a channel length of each of the channel layers 230c extends in a vertical direction Z from the semiconductor substrate 205.

On the peripheral circuit area PA′, the lower structure 203 may further include a peripheral active region 307a disposed on the semiconductor substrate 205, a peripheral device isolation region 307s on a side surface of the peripheral active region 307a, a peripheral gate structure 323 disposed on the peripheral active region 307a, and peripheral source/drain regions 331 disposed in the peripheral active region 307a on both sides of the peripheral gate structure 323.

The peripheral gate structure 323 may include a peripheral gate dielectric 324, a peripheral gate electrode 325 on the peripheral gate dielectric 324, and a peripheral gate capping layer 327 on the peripheral gate electrode 325. The peripheral gate capping layer 327 may be formed of an insulating material. The peripheral gate electrode 325 and the peripheral source/drain regions 331 may constitute a peripheral transistor PTR′.

In the peripheral circuit area PA′, the lower structure 203 may further include a lower insulating layer 340 covering the peripheral transistor PTR′.

In the memory cell area MA′, the lower structure 203 may further include a lower insulating layer 212 disposed on the semiconductor substrate 205. On the lower insulating layer 212, the plurality of first conductive lines 220 may be spaced apart from each other in the first horizontal direction X and extend in the second horizontal direction Y.

On the memory cell area MA′, the lower structure 203 may further include a plurality of first lower insulating patterns 222 filling a space between the plurality of first conductive lines 220, on the lower insulating layer 212. The plurality of first lower insulating patterns 222 may extend in the second horizontal direction Y, and upper surfaces of the plurality of first lower insulating patterns 222 may be disposed on the same level as upper surfaces of the plurality of first conductive lines 220. The plurality of first conductive lines 220 may function as bit lines of the semiconductor device 200 according to an example embodiment.

In example embodiments, the plurality of first conductive lines 220 may include doped polysilicon, a metal, a conductive metal nitride, a conductive metal silicide, a conductive metal oxide, or combinations thereof. For example, the plurality of first conductive lines 220 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or combinations thereof, but are not limited thereto. The plurality of first conductive lines 220 may include a single layer or multiple layers of the aforementioned materials. In example embodiments, the plurality of first conductive lines 220 may include a 2D semiconductor material, e.g., graphene, carbon nanotubes, or a combination thereof.

The channel layers 230c may be arranged in a matrix form to be spaced apart from each other in the first horizontal direction X and the second horizontal direction Y, on the plurality of first conductive lines 220. The lower source/drain regions 230s, the channel layers 230c, and the upper source/drain regions 230d may be sequentially stacked. In example embodiments, one channel layer 230c and the lower and upper source/drain regions 230s and 230d disposed below/on the one channel layer 230c may have a first width in the second horizontal direction X and a first height in a vertical direction Z, and the first height may be greater than the first width. For example, the first height may be about 2 to about 10 times the first width, but is not limited thereto.

In example embodiments, the channel layers 230c may include an oxide semiconductor. For example, the oxide semiconductor may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or combinations thereof. The channel layers 230c may include a single layer or multiple layers of the oxide semiconductor. In some examples, the channel layers 230c may have a band gap energy greater than that of silicon. For example, the channel layers 230c may have a band gap energy of about 1.5 eV to about 5.6 eV. For example, when the channel layer 230c has a band gap energy of about 2.0 eV to about 4.0 eV, the channel layer 230c may have optimal channel performance. For example, the channel layers 230c may be polycrystalline or amorphous, but are not limited thereto.

In example embodiments, the channel layers 230c may include a 2D semiconductor material, e.g., graphene, carbon nanotubes, or a combination thereof. In example embodiments, the channel layers 230c may include a semiconductor material, e.g., silicon or the like.

Hereinafter, a description will be provided focusing on one channel layer 230c and one cell gate electrode 240.

The cell gate electrode 240 may extend in the second horizontal direction X on both sidewalls of the channel layer 230c. The cell gate electrode 240 may include a first sub-gate electrode 240P1 facing a first sidewall of the channel layer 230c, and a second sub-gate electrode 240P2 facing a second sidewall of the channel layer 230c opposite to the first sidewall. As one channel layer 230c is disposed between the first sub-gate electrode 240P1 and the second sub-gate electrode 240P2, the semiconductor device 200 according to an example embodiment may have a dual gate transistor structure. However, embodiments are not limited thereto, and the second sub-gate electrode 240P2 is omitted and only the first sub-gate electrode 240P1 facing the first sidewall of the channel layer 230c may also be formed to implement a single gate transistor structure.

The cell gate electrode 240 may include doped polysilicon, metal, conductive metal nitride, conductive metal silicide, conductive metal oxide, or combinations thereof. For example, the cell gate electrode 240 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or combinations thereof, but the material thereof is not limited thereto.

The cell gate dielectric 250 may surround a sidewall of the channel layer 230c and may be interposed between the channel layer 230c and the cell gate electrode 240. For example, as illustrated in FIG. 3, the entire sidewall of the channel layer 230c may be surrounded by the cell gate dielectric 250, and a portion of the sidewall of the cell gate electrode 240 may contact the cell gate dielectric 250. In other embodiments, the cell gate dielectric 250 extends in an extension direction of the cell gate electrode 240, e.g., in a second horizontal direction X, and among sidewalls of the channel layer 230c, only two sidewalls facing the cell gate electrode 240 may contact the cell gate dielectric 250.

In example embodiments, the cell gate dielectric 250 may be formed of a silicon oxide film, a silicon oxynitride film, a high dielectric film having a higher dielectric constant than that of the silicon oxide film, or combinations thereof. The high dielectric film may be formed of a metal oxide or a metal oxynitride. For example, the high dielectric film usable as the cell gate dielectric 250 may be formed of HfO₂, HfSiO, HfSiON, HfTaO, HfTIO, HfZrO, ZrO₂, Al₂O₃, or combinations thereof, but is not limited thereto.

On the memory cell area MA′, the lower structure 203 may further include a plurality of second lower insulating patterns 232 disposed on the plurality of first lower insulating patterns 222. The second lower insulating patterns 232 may extend in the second horizontal direction Y, and the channel layer 230c may be disposed between adjacent two second lower insulating patterns 232 among the plurality of second lower insulating patterns 232.

On the memory cell area MA′, the lower structure 203 may further include a first buried layer 234 and a second buried layer 236 disposed in a space between two adjacent channel layers 230c, between two adjacent second lower insulating patterns 232. The first buried layer 234 is disposed on the bottom of the space between two adjacent channel layers 230c, and the second buried layer 236 may be formed to fill the remainder of the space between two adjacent channel layers 230c, on the first buried layer 234. The upper surface of the second buried layer 236 is disposed on the same level as the upper surface of the channel layer 230c, and the second buried layer 236 may cover the upper surface of the cell gate electrode 240. Unlike this, the plurality of second lower insulating patterns 232 may be formed as a material layer continuous with the plurality of first lower insulating patterns 222, or the second buried layer 236 may be formed as a material layer continuous with the first buried layer 234.

The pad patterns 260c disposed on the memory cell area MA′ and the wiring patterns 260p disposed on the peripheral circuit area PA′ may be formed of the same material. The pad patterns 260c may be disposed on the upper source/drain region 230d. The pad patterns 260c may be vertically overlapped with the channel layers 230c, respectively, and may be arranged in a matrix form, to be spaced apart in the first horizontal direction X and the second horizontal direction Y. The pad patterns 260c and the wiring patterns 260p may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or combinations thereof, but are not limited thereto.

For example, each of the pad patterns 260c and the wiring patterns 260p may include a first conductive material layer 259a and a second conductive material layer 259b on the first conductive material layer 259a. In another example, contact patterns may be disposed between the second source/drain regions 230d and the pad patterns 260c. For example, in FIG. 4A, reference numeral 259a may be referred to as a contact pattern, and reference numeral 259b may be referred to as a pad pattern.

At least one of the wiring patterns 260p may include a wiring portion 260p1 on the lower structure 203, and a plug portion 260p2 extending from the wiring portion 260p1 into the lower structure 203 and electrically connected to the peripheral transistor PTR′.

In example embodiments, the lower structure 203 may further include a metal-semiconductor compound layer 346 electrically connecting the peripheral source/drain region 331 and the plug portion 260p2, between the peripheral source/drain region 331 and the plug portion 260p2.

Each of the pad patterns 260c may have a first side (S1) and a second side (S2) that oppose each other and are parallel to each other, and a third side (S3) and a fourth side (S4) that oppose each other and are parallel to each other. Each of the pad patterns 260c has the first to fourth sides S1, S2, S3 and S4, and may have a rounded shape in areas in which the first to fourth sides S1, S2, S3 and S4 meet each other. For example, when viewed in a plan view, each of the pad patterns 260c has edges such as the first to fourth sides S1, S2, S3 and S4, and may have a rounded shape in portions in which the edges S1, S2, S3 and S4 are adjacent to each other. In example embodiments, each of the pad patterns 260c may have an oval shape, a circle shape, or a quadrangular shape in which vertices are rounded.

In example embodiments, when viewed in a plan view, in each of the pad patterns 260c, the first and second sides S1 and S2 may have a line shape extending in a diagonal direction D1′ forming an acute angle with respect to the first horizontal direction X, and the third and fourth sides S3 and S4 may have a line shape extending in a second diagonal direction D2′ forming an obtuse angle with respect to the first horizontal direction X. In example embodiments, in a plan view, among the pad patterns 260c, in pad patterns sequentially arranged in the first diagonal direction D1′, the first sides S1 may be aligned in the first diagonal direction D1′, and the second sides S2 may be aligned in the first diagonal direction D1′.

In example embodiments, in a plan view, among the pad patterns 260c, in the pad patterns sequentially arranged in the second diagonal direction D2′, the third sides S3 may be aligned in the second diagonal direction D2, and the fourth sides S4 may be aligned in the second diagonal direction D2′.

On the memory cell area MA′, the lower structure 203 may further include first insulating patterns 262a. The first insulating patterns 262a may surround sidewalls of the pad patterns 260c, on the plurality of second lower insulating patterns 232 and the second buried layer 236.

On the memory cell area MA′, the lower structure 203 may further include an etch stop layer 270 disposed on the first insulating patterns 262a, and a data storage structure 280 disposed on the etch stop layer 270.

In example embodiments, the data storage structure 280 may be a capacitor that stores information in a DRAM. For example, the data storage structure 280 may include first electrodes 282, a dielectric layer 284, and a second electrode 286. The first electrodes 282 may penetrate through the etch stop layer 270 and are electrically connected to the upper surfaces of the pad patterns 260c. The first electrodes 282 may be formed in a pillar type extending in the vertical direction Z, but are not limited thereto. In example embodiments, the first electrodes 282 may be disposed to vertically overlap the pad patterns 260c and may be arranged in a matrix form to be spaced apart in the first horizontal direction X and the second horizontal direction Y.

In another embodiment, the data storage structure 280 may be a data storage structure capable of storing information in a nonvolatile memory device, e.g., an MRAM device or a variable resistance memory device.

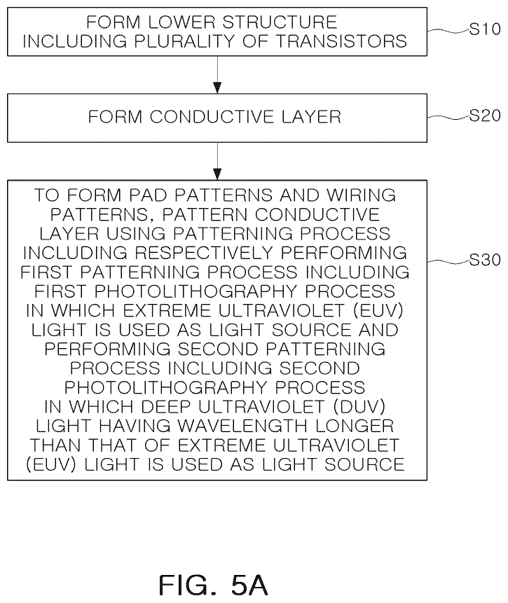

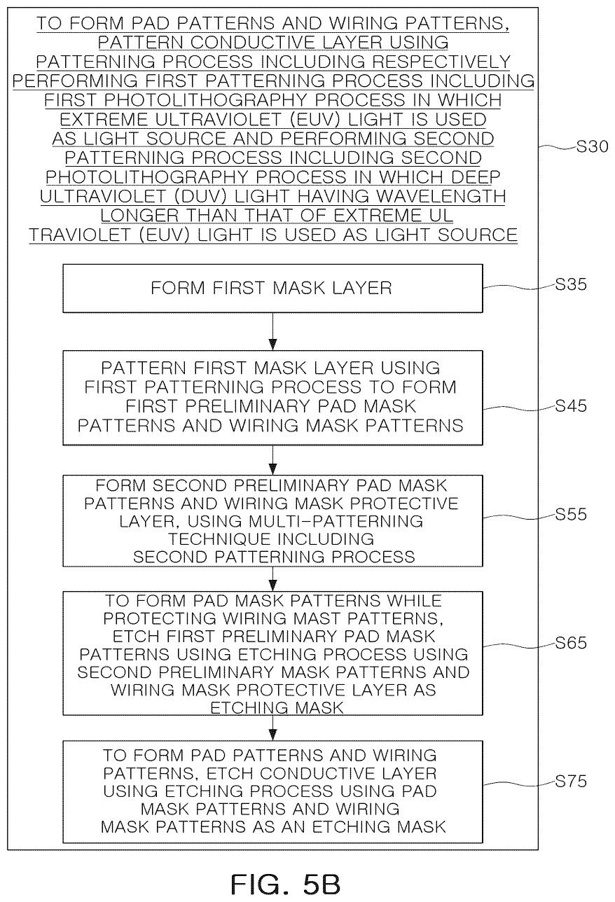

Next, example embodiments of a method of manufacturing a semiconductor device according to an example embodiment will be described with reference to FIG. 5A. FIG. 5A is a flowchart schematically illustrating a method of manufacturing a semiconductor device according to an example embodiment.

Referring to FIG. 5A, a lower structure including a plurality of transistors may be formed (S10). For example, the lower structure may be the lower structure 3 described with reference to FIGS. 1A to 2B. In another example, the lower structure may be the lower structure 203 described with reference to FIGS. 3 to 4B.

Next, a conductive layer may be formed on the lower structure (S20). For example, the conductive layer may be formed of the same material as the pad patterns 49c and the wiring patterns 49p described with reference to FIGS. 1A to 2B. In another example, the conductive layer may be formed of the same material as the pad patterns 260c and the wiring patterns 260p described with reference to FIGS. 3 to 4B.

Subsequently, the conductive layer may be patterned to form pad patterns and the wiring patterns (S30). The pad patterns and the wiring patterns may be formed by using a patterning process including respectively performing a first patterning process including a first photolithography process, in which extreme ultraviolet (EUV) light is used as a light source, and performing a second patterning process including a second photolithography process, in which deep ultraviolet (DUV) light having a wavelength longer than that of the EUV light is used as a light source.

For example, the pad patterns and the wiring patterns may be the pad patterns 49c and the wiring patterns 49p described with reference to FIGS. 1A to 2B. In another example, the pad patterns and the wiring patterns may be the pad patterns 260c and the wiring patterns 260p described with reference to FIGS. 3 to 4B.

Next, with reference to FIG. 5B, operation S30 will be described in detail. FIG. 5B is a process flow diagram of stages in operation S30 described in FIG. 5A.

Referring to FIG. 5B, a first mask layer may be formed (S35), the first mask layer may be patterned using a first patterning process to form first preliminary pad mask patterns and wiring mask patterns (S45), second preliminary pad mask patterns and a wiring mask protective layer may be formed using a multi-patterning technique including a second patterning process (S55), the first preliminary pad mask patterns may be etched using an etching process using the second preliminary mask patterns and the wiring mask protective layer as an etching mask to form the pad mask patterns while protecting the wiring mast patterns (S65), and a conductive layer may be etched using an etching process using the pad mask patterns and the wiring mask patterns as an etching mask to form the pad patterns and wiring patterns (S75). Accordingly, pad patterns and wiring patterns as described in FIG. 5A may be formed. Accordingly, operation S30 described in FIG. 5A may include operations S35, S45, S55, S65, and S75 described with reference to FIG. 5B.

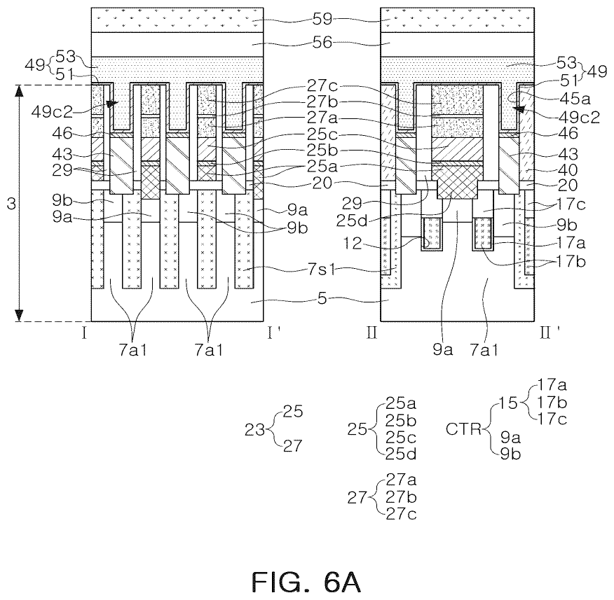

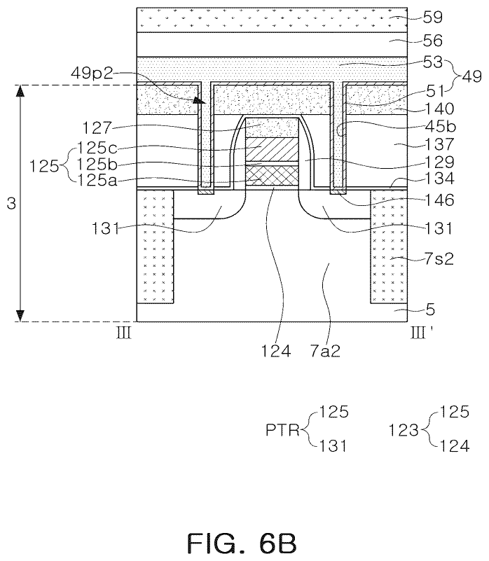

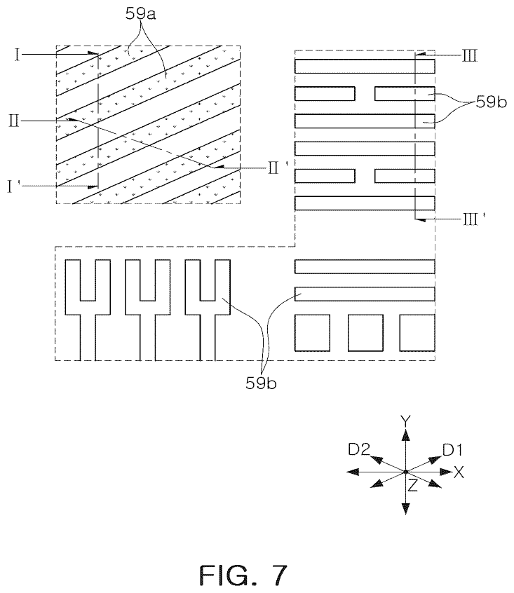

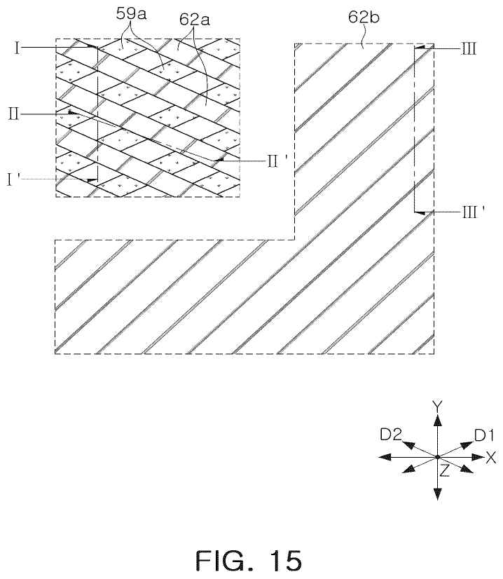

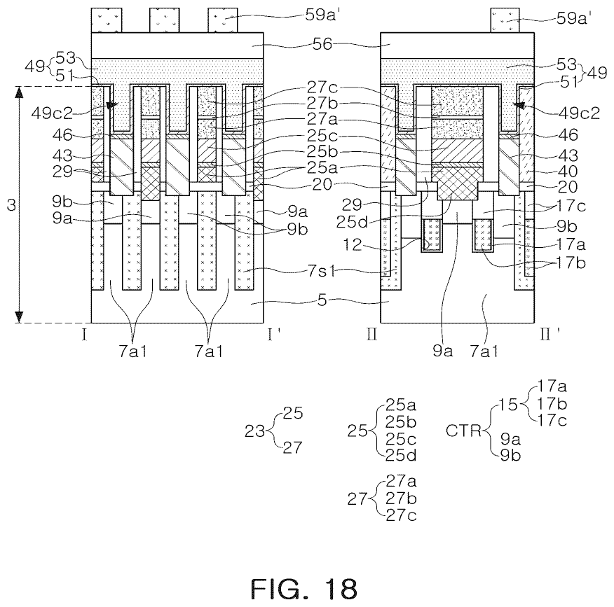

Next, example embodiments of a method of manufacturing a semiconductor device according to an example embodiment will be described mainly with reference to FIGS. 6A to 19B. FIGS. 6A to 19B are cross-sectional views of stages in a method of manufacturing a semiconductor device according to an example embodiment. FIGS. 6A, 8A, 10A, 11A, 12A, 13A, 14A, 16, 17A, 18, and 19A illustrate cross-sectional views along lines I-I′ and II-II′ of FIG. 1A of stages in the method of manufacturing a semiconductor device according to an example embodiments. FIGS. 6B, 8B, 10B, 11B, 12B, 13B, 14B, 17B, and 19B illustrate cross-sectional views along line III-III′ of FIG. 1A of stages in a method of manufacturing a semiconductor device according to an example embodiment. FIGS. 7, 9A, 9B and 15 illustrate plan views of stages in the method of manufacturing a semiconductor device according to an example embodiment.

Referring to FIGS. 1A, 5A, 5B, 6A, and 6B, the lower structure 3 including the plurality of transistors CTR and PTR may be formed (see S10 in FIG. 5A). As described in FIG. 5A, the lower structure 3 may be the lower structure 3 described with reference to FIGS. 1A to 2B, but embodiments not limited thereto. For example, the lower structure 3 may be replaced with the lower structure 203 described with reference to FIGS. 3 to 4B.

A conductive layer 49 may be formed (see S20 in FIG. 5A). In example embodiments, forming the conductive layer 49 may include forming first openings 45a exposing upper surfaces of the contact plugs 43 on the memory cell area MA and second openings 45b exposing the second source/drain regions 131 on the peripheral circuit area PA, by etching a portion of the lower structure 3, and forming a conductive material layer covering the upper surface of the lower structure 3 while filling the first and second openings 45a and 45b. The conductive layer 49 may include a first conductive material layer 51 and a second conductive material layer 53 that are sequentially formed.

In example embodiments, after forming the first and second openings 45a and 45b, before forming the conductive material layer filling the first and second openings 45a and 45b, first metal-semiconductor compound layers 46 and second metal-semiconductor compound layers 146 may be formed on the exposed surfaces of the contact plugs 43 and the exposed surfaces of the second source/drain regions 131, respectively. For example, the first and second metal-semiconductor compound layers 46 and 146 may include the same material, e.g., metal silicides such as TiSi, CoSi, WSi, TaSi, NiSi, MoSi or the like.

A lower layer 56 may be formed on the conductive layer 49. The lower layer 56 may be formed of a material having etch selectivity with respect to the conductive layer 49. For example, the lower layer 56 may be formed of an amorphous carbon layer, a polysilicon layer, a silicon oxide, a silicon nitride, a silicon oxynitride, or combinations thereof, but the material is not limited thereto. The lower layer 56 may be formed of a single layer or multiple layers of the aforementioned materials.

The first mask layer 59 may be formed (35 in FIG. 5B). The first mask layer 59 may be formed on the lower layer 56. The first mask layer 59 may be formed of an amorphous carbon layer, a polysilicon layer, a silicon oxide layer, a silicon nitride layer, a silicon oxynitride layer, or combinations thereof, but the configuration is not limited thereto. The lower layer 56 may be formed of a single layer or multiple layers of the aforementioned materials.

In example embodiments, a portion of the first mask layer 59 and a portion of the lower layer 56 adjacent to each other may be formed of different materials.

Referring to FIGS. 1A, 5B, 7, 8A and 8B, the first mask layer (59 in FIGS. 6A and 6B) may be patterned using the first patterning process (see S45 in FIG. 5B) to form first preliminary pad mask patterns 59a and wiring mask patterns 59b. Accordingly, forming the first preliminary pad mask patterns 59a and the wiring mask patterns 59b may include forming the first mask layer 59 on the conductive layer 49, and patterning the first mask layer (59 in FIGS. 6A and 6B) using the first patterning process using the first photolithography process in which EUV light is used as a light source.

The first patterning process may include a first photolithography process using EUV light as a light source, as described in operation S30 in FIGS. 5A and 5B. In example embodiments, the EUV light may have a wavelength between about 4 nm and about 124 nm, e.g., about 4 nm to about 20 nm. For example, the EUV light may have a wavelength of about 13.5 nm. The first photolithography process may use a reflective EUV photomask that reflects extreme ultraviolet rays.

For example, as illustrated in FIG. 7, at least one of the wiring mask patterns 59b has a first line shape extending in the first horizontal direction X, and each of the first preliminary pad mask patterns 59a may have a second line shape extending in the first diagonal direction D1 forming an acute or obtuse angle with respect to the first horizontal direction.

For example, the wiring mask patterns 59b may include a wiring mask pattern having a line shape extending in the first horizontal direction X or a wiring mask pattern having a line shape extending in a second horizontal direction Y perpendicular to the first horizontal direction X. For example, if the wiring mask patterns 59b extends in the first horizontal direction X, the first diagonal direction D1 may form an acute angle with respect to the first horizontal direction X. In another example, if the wiring mask patterns 59b extending in the second horizontal direction Y, the first diagonal direction D1 may form an obtuse angle with respect to the second horizontal direction Y.

Referring to FIGS. 1A, 9A, 9B, 10A, and 10B, a second mask layer 62 covering the first preliminary pad mask patterns 59a and the wiring mask patterns 59b, on the lower layer 56, may be formed. The second mask layer 62 may include a first material layer 64a, and a second material layer 64b on the first material layer 64a. The first material layer 64a and the second material layer 64b may be formed of different materials. For example, the first material layer 64a and the second material layer 64b may be formed of different layers, e.g., the first material layer 64a and the second material layer 64b may independently include an amorphous carbon layer, a polysilicon layer, a silicon oxide layer, a silicon nitride layer, a silicon oxynitride layer, and/or a spin on hardmask (SOH) material layer.

An upper layer 67 may be formed on the second mask layer 62. The upper layer 67 may include a first upper material layer 69a, and a second upper material layer 69b on the first upper material layer 69a. The first upper material layer 69a and the second upper material layer 69b may be formed of different materials. For example, the first upper material layer 69a and the second upper material layer 69b may be formed of different layers, e.g., the first upper material layer 69a and the second upper material layer 69b may independently include an amorphous carbon layer, a polysilicon layer, a silicon oxide layer, a silicon nitride layer, a silicon oxynitride layer, and/or a spin on hardmask (SOH) material layer.

A capping mask layer 72 may be formed on the upper layer 67. The capping mask layer 72 may be formed of, e.g., an amorphous carbon layer, a polysilicon layer, a silicon oxide layer, a silicon nitride layer, a silicon oxynitride layer, or combinations thereof, but the configuration is not limited thereto. The capping mask layer 72 may be formed of a single layer or multiple layers of the aforementioned materials.

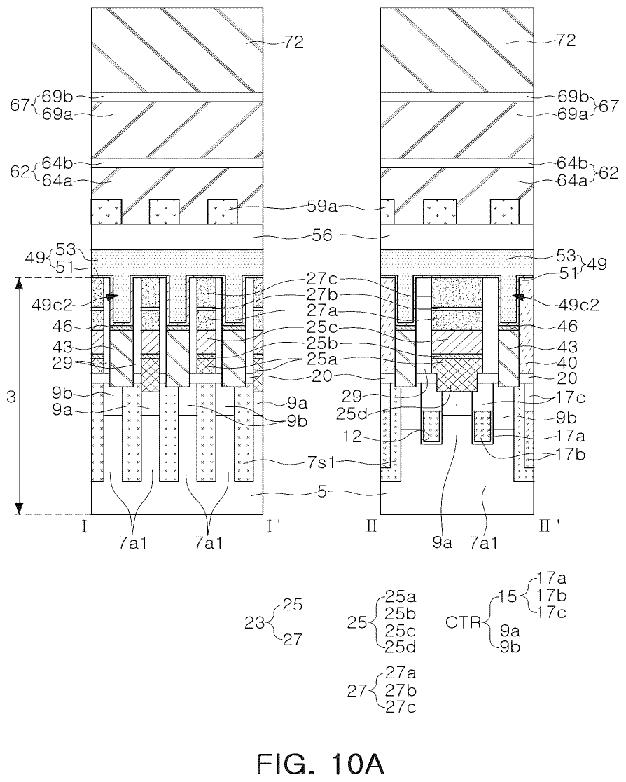

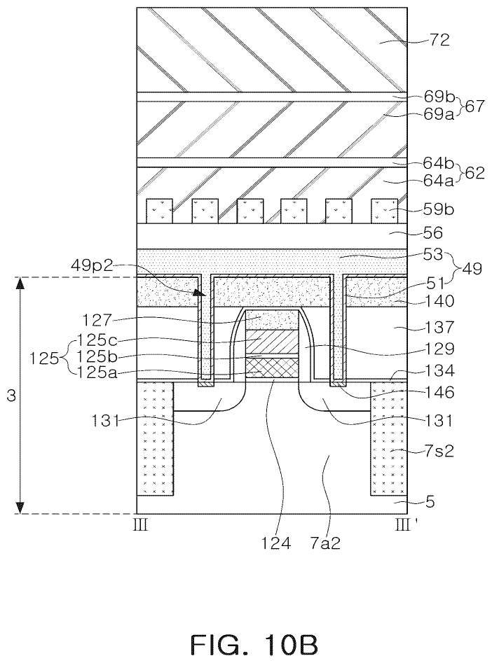

Referring to FIGS. 1A, 9A, 9B, 11A, and 11B, the capping mask layer (72 in FIGS. 10A and 10B) may be patterned to form capping mask patterns 72a and a protective mask pattern 72b, by using a second photolithography process in which DUV light having a wavelength longer than a wavelength of the EUV light is used as a light source.

In example embodiments, the DUV light may be an ArF excimer laser having a wavelength of about 193 nm, but is not limited thereto, and may be a g-line of a wavelength of about 436 nm, an i-line (365 nm) of a wavelength of about 365 nm, or a KrF laser of a wavelength of about 248 nm. In example embodiments, the second photolithography process may use a transmissive photomask. In example embodiments, the second photolithography process may be a photolithography process using immersion ArF exposure equipment.

In example embodiments, each of the capping mask patterns 72a may have a line shape extending in a second diagonal direction D2 forming an obtuse angle with respect to the first horizontal direction X. The second diagonal direction D2 may intersect the first diagonal direction D1. Accordingly, the capping mask patterns 72a may intersect the first preliminary pad mask patterns 59a.

The protective mask pattern 72b may have a plate shape covering the wiring mask patterns 59b. For example, the protective mask pattern 72b may cover the wiring mask patterns 59b and the entire space between the wiring mask patterns 59b.

Each of the first preliminary pad mask patterns 59a may be formed to have a first width, and each of the capping mask patterns 72a may be formed to have a second width greater than the first width. The first preliminary pad mask patterns 59a may be spaced apart at a first interval, and the capping mask patterns 72a may be spaced apart at a second interval greater than the first interval.

A first liner layer 77 may be formed to cover the capping mask patterns 72a and the protective mask pattern 72b with a substantially uniform thickness, on the upper layer 67. The first liner layer 77 may be formed by an atomic layer deposition process. For example, the first liner layer 77 may be formed of silicon oxide.

An upper capping layer 80 overlapping the protective mask pattern 72b may be formed on the first liner layer 77. The upper capping layer 80 may not overlap the capping mask patterns 72a. The upper capping layer 80 may be a photoresist layer.

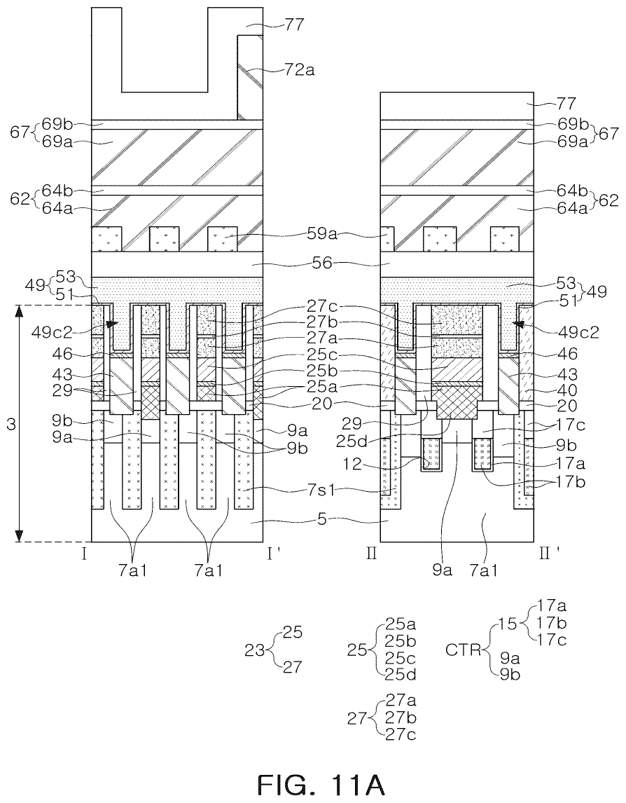

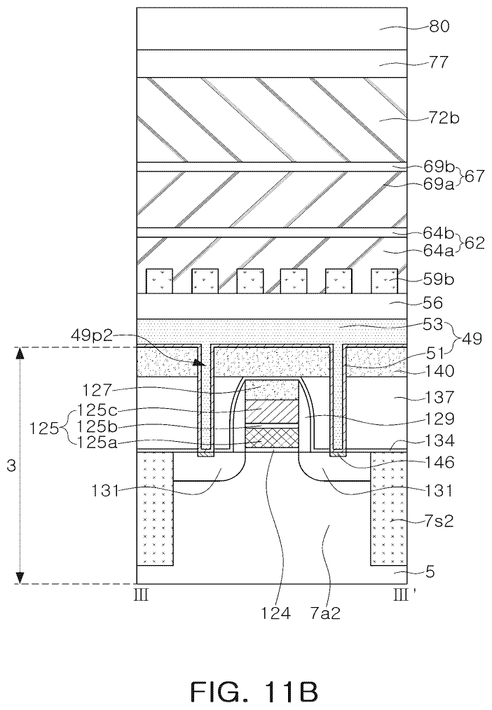

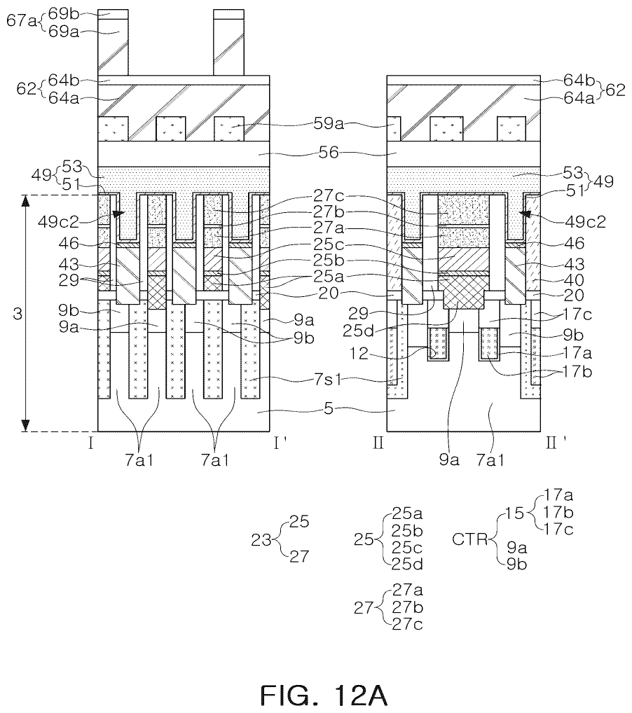

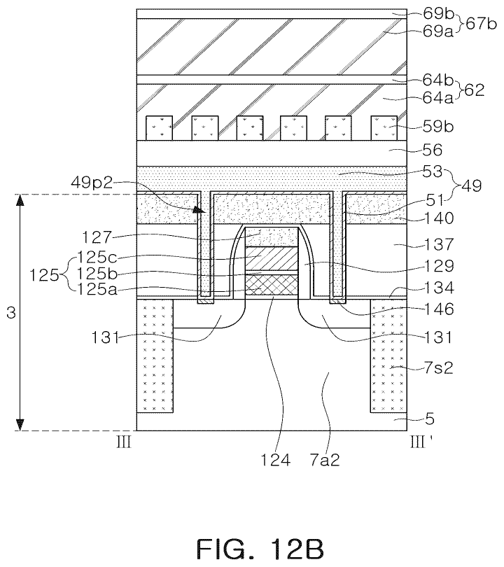

Referring to FIGS. 1A, 12A, and 12B, the first liner layer (77 in FIG. 11A) that does not overlap with the upper capping layer 80 is anisotropically etched to form portions of the first liner layer (77 in FIG. 11A) remaining on side surfaces of the capping mask patterns (72a in FIG. 11A). The upper capping layer (80 in FIG. 11B) and the capping mask patterns (72a in FIG. 11A) may be removed.

To form first upper patterns 67a and an upper protective layer 67b, the upper layer 67 is etched using an etching process using the first liner layer (77 in FIG. 11A) as an etching mask, and in addition, the first liner layer (77 in FIG. 11B) and the protective mask pattern 72b may be removed. The upper protective layer 67b may be formed below the protective mask pattern 72b.

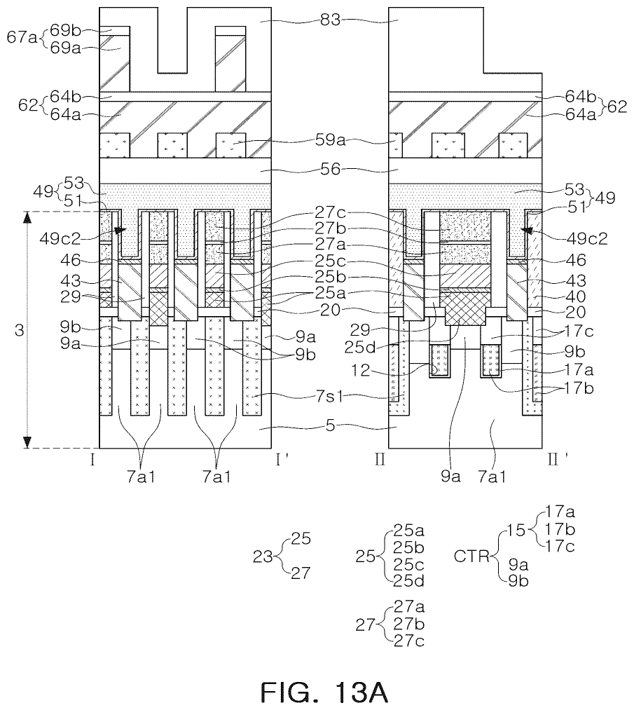

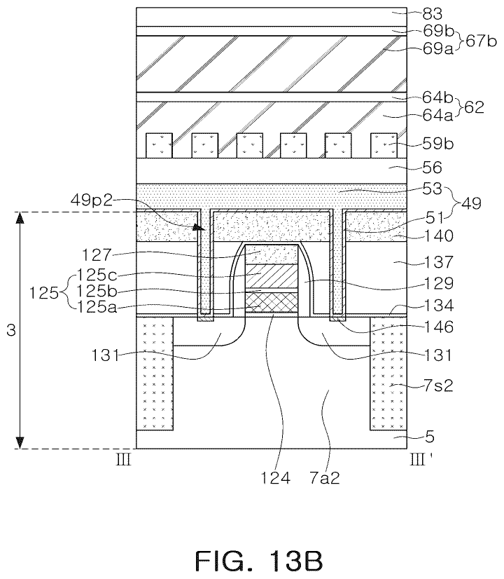

Referring to FIGS. 1A, 13A, and 13B, a second liner layer 83 may be formed to cover the first upper patterns 67a and the upper protective layer 67b with a substantially uniform thickness, on the second mask layer 62. The second liner layer 83 may be formed by an atomic layer deposition process. For example, the second liner layer 83 may be formed of silicon oxide.

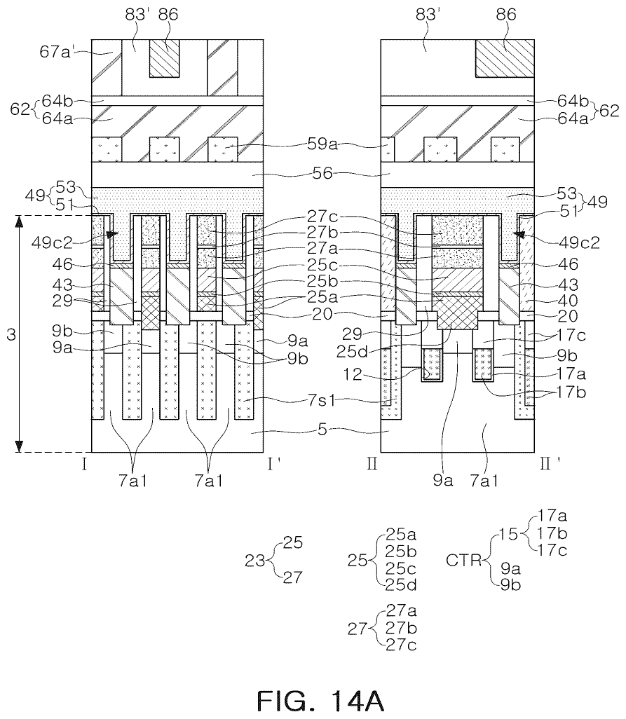

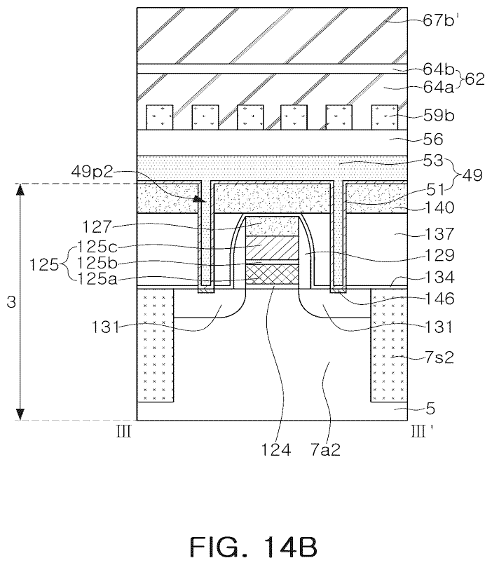

Referring to FIGS. 1A, 14A, and 14B, gap fill patterns 86 may be formed on the second liner layer (83 in FIG. 13A) positioned between the first upper patterns (67a in FIG. 13A). Lower and side surfaces of each of the gap fill patterns 86 may contact the second liner layer (83 in FIG. 13A).

By performing a planarization process, a portion of the second liner layer (83 in FIGS. 13A and 13B) disposed on upper surfaces of the first upper patterns (67a in FIG. 13A) and the upper protective layer 67b may be removed, and in addition, the thickness of the first upper patterns (67a in FIG. 13A) and the thickness of the upper protective layer 67b may be reduced. In an example, the planarization process may include an etch back process. Accordingly, a first upper patterns 67a′ having a reduced thickness, an upper protective layer 67b′ having a reduced thickness, and a second liner layer 93′ having a reduced thickness may be formed.

Referring to FIGS. 1A, 15, and 16, to form second liner patterns 83′ remaining below the gap fill patterns 86, the second liner layer (83′ in FIG. 14A) having a reduced thickness may be anisotropically etched. The second liner patterns 83′ and the gap fill patterns 86 sequentially stacked may be defined as second upper patterns 88.

The second upper patterns 88 and the first upper patterns 67a′ may have parallel line shapes. The first upper patterns 67a′ may be repeatedly arranged alternately with the second upper patterns 88.

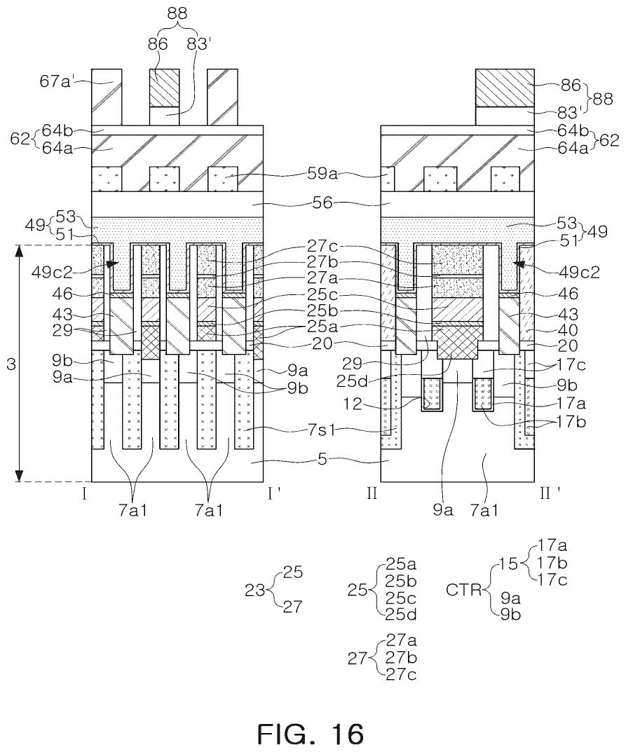

Referring to FIGS. 1A, 5B, 15, 17A, and 17B, to form second preliminary pad mask patterns 62a and a wiring mask protective layer 62b, the second mask layer (62 in FIGS. 16 and 14B) may be etched by an etching process in which the first upper patterns (67a′ in FIG. 16), the second upper patterns (88 of FIG. 16), and the upper protective layer (67b′ of FIG. 14B) are used as an etching mask. While etching the second mask layer (62 in FIGS. 16 and 14B), the first upper patterns (67a′ in FIG. 16), the second upper patterns (88 in FIG. 16), and the upper protective layer (67b′ in FIG. 14B) may be removed by etching.

In example embodiments, the second preliminary pad mask patterns 62a and the wiring mask protective layer 62b may be formed using a multi-patterning technique including a second patterning process (see S55 in FIG. 5B). In example embodiments, the second patterning process uses a second photolithography process, in which DUV light having a wavelength longer than that of the EUV light described with reference to FIGS. 11A and 11B is used as a light source, thereby patterning the capping mask layer (72 in FIGS. 10A and 10B).

In example embodiments, the multi-patterning technique may include performing a patterning process that includes performing a second photolithography process using the DUV light as a light source at least once. In example embodiments, the multi-patterning technique may include performing a patterning process once or at least twice, the patterning process including performing a deposition process and an etching process without a photolithography process.

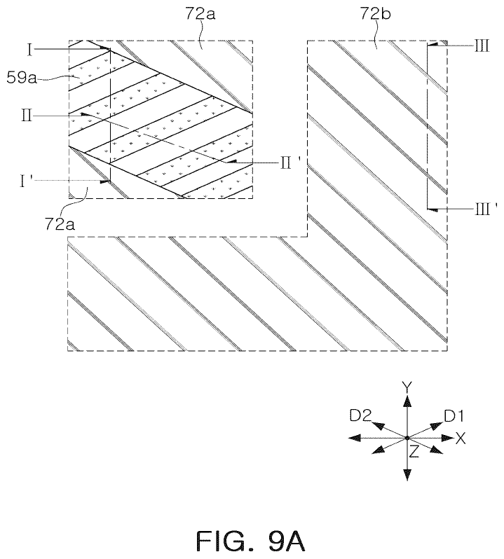

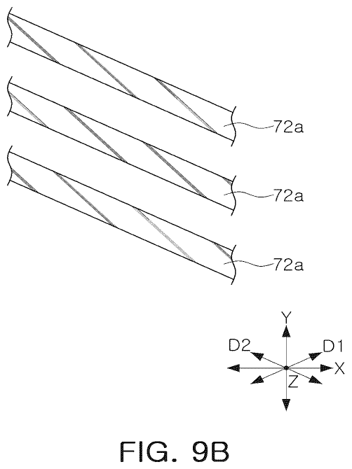

For example, in the multi-patterning technique, a single patterning process including a deposition process and an etching process may include a deposition process for forming the capping mask layer (72 in FIGS. 10A and 10B) as described in FIGS. 10A and 10B, and an etching process of etching the capping mask layer (72 in FIGS. 10A and 10B) to form the capping mask patterns 72a and the protective mask pattern 72b as in FIGS. 9A, 9B, 11A, and 11B.

In the multi-patterning technique, a single patterning process including a deposition process and an etching process without a photo process may include a deposition process for forming the first liner layer (77 in FIGS. 11A and 11B) as described in FIGS. 11A and 11B, and an etching process of etching the first liner layer (77 in FIG. 11A) to form portions of the first liner layer (77 in FIG. 11A) remaining on the side surfaces of the capping mask patterns (72a in FIG. 11A) as described in FIGS. 12A and 12B.

In the multi-patterning technique, another patterning process that is performed once and includes a deposition process and an etching process may include a deposition process for forming the second liner layer 83 as described in FIGS. 13A and 13B, and an etching process of etching the second liner layer (83′ in FIG. 14A) to form second liner patterns 83′ remaining below the gap fill patterns 86 as described with reference to FIG. 16.

Therefore, to form the second preliminary pad mask patterns 62a and the wiring mask protective layer 62b, the multi-patterning technique that includes performing a patterning process including a deposition process and an etching process once or at least twice may be used, thereby patterning the second mask layer 62. The thickness of each of the second preliminary pad mask patterns 62a and the wiring mask protective layer 62b may be less than the thickness of the second mask layer (62 in FIGS. 16 and 14B).

At least one of the wiring mask patterns 59b may have a shape of a first line extending in the first horizontal direction X, and each of the first preliminary pad mask patterns 59a may have a shape of a second line extending in the first diagonal direction D1 forming an acute or obtuse angle with respect to the first horizontal direction X, and each of the second preliminary pad mask patterns 62a may have a shape of a third line extending in the second diagonal direction D2 intersecting the first diagonal direction D1. The first horizontal direction D1, the first diagonal direction D1, and the second diagonal direction D2 may be parallel to any one plane of the lower structure 3. One plane of the lower structure 3 may be an upper surface of the semiconductor substrate 5, a lower surface of the semiconductor substrate 5, upper surfaces of the bit lines 25, or an upper surface of the lower structure 3.

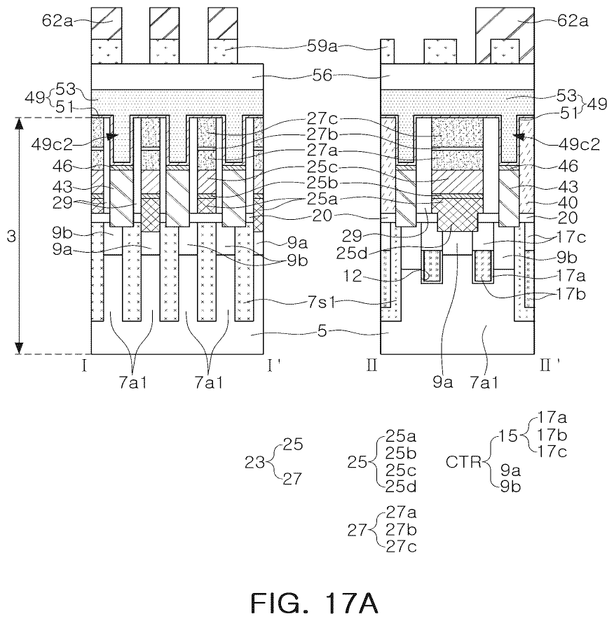

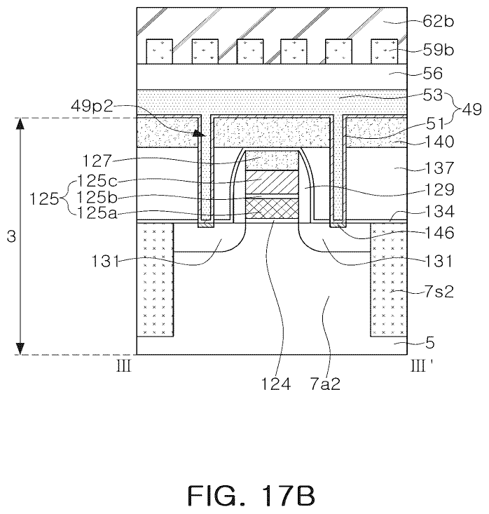

Referring to FIGS. 1A, 5B, and 18, to form pad mask patterns 59a′ while protecting the wiring mask patterns (59b of FIG. 17B), the first preliminary pad mask patterns (62a in FIG. 17A) may be etched using an etching process in which the second preliminary pad mask patterns (62a in FIG. 17A) and the wiring mask protective layer (62b in FIG. 17B) are used as an etching mask (S65 of FIG. 5B). Accordingly, the first preliminary pad mask patterns (62a of FIG. 17A) having a line shape may be formed as the pad mask patterns 59a′ having a dot shape.

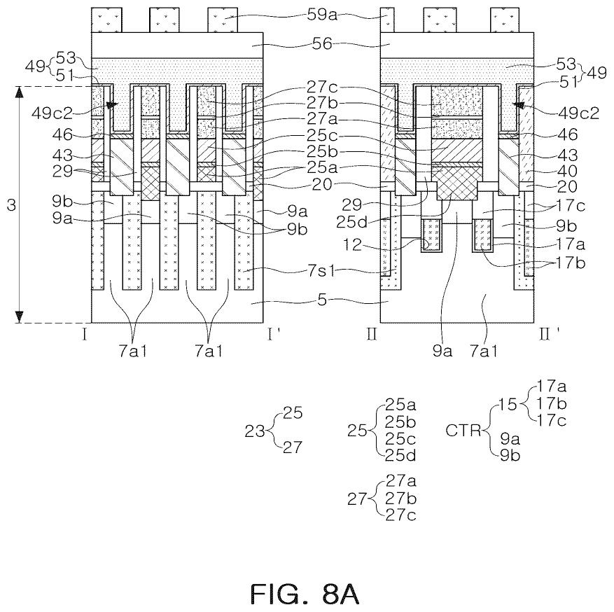

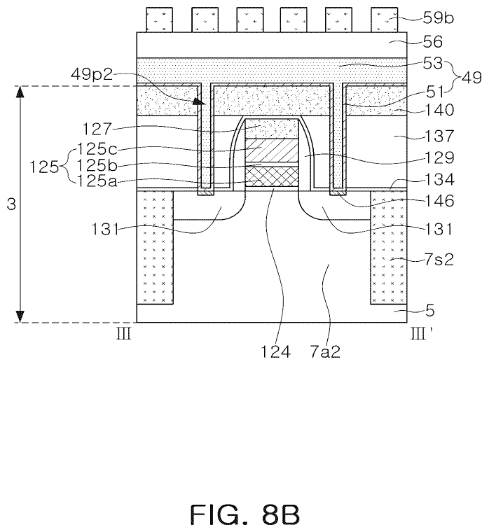

Subsequently, the second preliminary pad mask patterns (62a in FIG. 17A) and the wiring mask protective layer (62b in FIG. 17B) may be removed. Accordingly, the pad mask patterns 59a′ may be formed while protecting the wiring mask patterns (59b of FIG. 8B) as illustrated in FIG. 8B.

Referring to FIGS. 1A, 5B, 19A, and 19B, to form the pad patterns 49c and wiring patterns 49p, the conductive layer 49 may be etched using an etching process in which pad mask patterns 59a′ and wiring mask patterns 59b are used as an etching mask (S75 in FIG. 5B). The etching process using the pad mask patterns 59a′ and the wiring mask patterns 59b as an etching mask may include sequentially etching the lower layer 56 and the conductive layer 49.

In example embodiments, after the etching process using the pad mask patterns 59a′ and the wiring mask patterns 59b as an etching mask is performed or during the etching process in which the pad mask patterns 59a′ and the wiring mask patterns 59b are used as an etching mask, the pad mask patterns 59a′ and the wiring mask patterns 59b may be removed.

For example, the lower layer 56 may be etched using the pad mask patterns 59a′ and the wiring mask patterns 59b as an etching mask, such that lower pad mask patterns 56a remaining below the pad mask patterns 59a′ and lower wiring mask patterns 56b remaining below the wiring mask patterns 59b are formed, and the conductive layer 49 may be exposed. Subsequently, the exposed conductive layer 49 may be etched to form pad patterns 49c remaining below the lower pad mask patterns 56a and wiring patterns 49p remaining below the lower wiring mask patterns 56b, and to form grooves 90 extending into the lower structure 3. Accordingly, the pad patterns 49c and the wiring patterns 49p as described with reference to FIGS. 2A and 2B may be formed.

In example embodiments, while the lower layer 56 is etched, the pad mask patterns 59a′ and the wiring mask patterns 59b may be etched and removed.

Again, referring to FIGS. 1A, 1B, 2A and 2B, first and second insulating patterns 92a and 92b filling the grooves 90 may be formed. The lower pad mask patterns 56a and the lower wiring mask patterns 56b may be removed while forming the first and second insulating patterns 92a and 92b.

An etch stop insulating layer 94 may be formed on the pad patterns 49c, the wiring patterns 49p, and the first and second insulating patterns 92a and 92b. A data storage structure 97 may be formed on the memory cell area MA. In forming the data storage structure 97, first electrodes 97a may be formed to penetrate through the etch stop insulating layer 94 and be electrically connected to the pad patterns 49c, and a dielectric layer 97b may be formed to conformally cover the first electrodes 97a, and a second electrode 97c may be formed to cover the dielectric layer 97b. The data storage structure 97 may be formed on the pad patterns 49c and the first insulating patterns 92a. An upper insulating layer 99 may be formed on the etch stop insulating layer 94 in the peripheral circuit area PA.

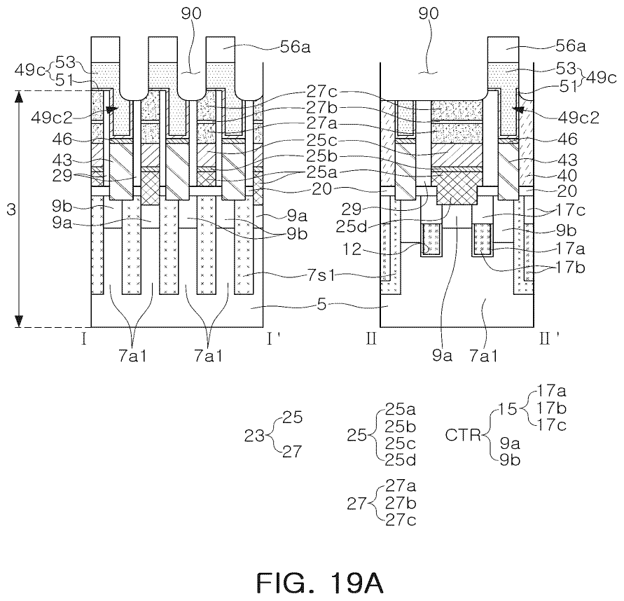

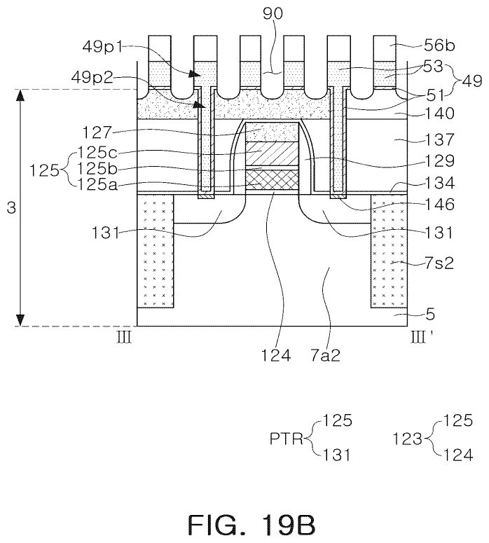

A method of manufacturing a semiconductor device according to the above-described embodiment may include forming a conductive layer (49 in FIGS. 6A and 6B) on a semiconductor substrate (5 in FIGS. 6A and 6B), and pattering the conductive layer (49 in FIGS. 6A and 6B) using the method described with reference to FIGS. 6A to 19B to form the pad patterns (49c in FIG. 19A) and the wiring patterns (49p in FIG. 19B). For example, patterning the conductive layer (49 in FIGS. 6A and 6B) may include respectively performing a first patterning process including a first photolithography process in which extreme ultraviolet (EUV) light is used as a light source as described with reference to FIGS. 1A, 5B, 7, 8A and 8B; and performing a second patterning process including a second photolithography process in which deep ultraviolet (DUV) light having a wavelength longer than a wavelength of the extreme ultraviolet (EUV) light, as described with reference to FIGS. 1A, 9A, 9B, 11A, and 11B, is used as a light source. In this case, the second patterning process may be performed after the first patterning process is performed.

By way of summation and review, example embodiments provide a semiconductor device in which integration and reliability may be improved, and a method of manufacturing the same. As set forth above, according to example embodiments, a method of manufacturing a semiconductor device including dot-shaped pad patterns and linear shape wiring patterns formed at the same height level, and a semiconductor device manufactured by the same may be provided.

That is, in example embodiments, dot-shaped pad patterns may be formed using a first photolithography process with EUV light as a light source and a second photolithography process with DUV light (having a wavelength longer than a wavelength of the EUV light) as a light source, and the line-shaped wiring patterns may be formed by the first photolithography process with EUV light as a light source without using the second photolithography process with the DUV light as a light source. In this manner, since the dot-shaped pad patterns and the line-shaped wiring patterns formed at the same height level may be formed stably and reliably, a semiconductor device having improved integration and reliability may be provided.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device comprising:
a first cell source/drain region, a second cell source/drain region, and a cell gate including a cell transistor;
a first peripheral source/drain region, a second peripheral source/drain region, and a peripheral gate including a peripheral transistor;
a bit line electrically connected to the first cell source/drain region;
a cell conductive structure electrically connected to the second cell source/drain region;
a peripheral conductive structure electrically connected to the first peripheral source/drain region; and
a data storage structure electrically connected to the cell conductive structure,
wherein the cell conductive structure includes:
a cell contact portion on the second cell source/drain region; and
a cell pad portion on the cell contact portion,
wherein the peripheral conductive structure includes:
a peripheral contact portion on the first peripheral source/drain region; and
a peripheral wiring portion on the peripheral contact portion,
wherein, in a plan view, the cell pad portion includes:
a first side and a second side opposing each other in a first direction;
a third side and a fourth side opposing each other in a second direction different from the first direction;
a first rounded corner where a first side and the fourth side meet;
a second rounded corner where a first side and the third side meet;
a third rounded corner where a second side and the third side meet; and
a fourth rounded corner where a second side and the fourth side meet,
wherein the first rounded corner and the third rounded corner oppose each other in a third direction,
wherein the second rounded corner and the fourth rounded corner oppose each other in a fourth direction perpendicular to the third direction, and
wherein the peripheral wiring portion has a line shape extending in the third direction.

2. The semiconductor device of claim 1, wherein a distance between the first rounded corner and the third rounded corner is different from a distance between the second rounded corner and fourth rounded corner.

3. The semiconductor device of claim 1, wherein a distance between the first rounded corner and the third rounded corner is greater than a distance between the second rounded corner and fourth rounded corner.

4. The semiconductor device of claim 1, wherein the cell gate extends in the fourth direction, and
wherein the bit line extends in the third direction.

5. The semiconductor device of claim 1, wherein a vertical central axis of the cell pad portion is not aligned with a vertical central axis of the cell pad portion.

6. The semiconductor device of claim 1, wherein the cell pad portion is at the same level as the peripheral contact portion.

7. The semiconductor device of claim 1, further comprising:
a first insulating pattern in contact with the first side, the second side, the third side, the fourth side, a first rounded corner, a second rounded corner, the third rounded corner, and the fourth rounded corner of the cell pad portion,
wherein a lower surface of the first insulating pattern is at a higher level than a lower surface of the cell contact portion.

8. The semiconductor device of claim 1, wherein the cell conductive structure further includes a plug portion downwardly extending from a portion of the cell pad portion, and
wherein the plug portion is aligned with the cell contact portion.

9. The semiconductor device of claim 1, wherein a peripheral contact portion extends downwardly from a portion of the peripheral wiring portion.

10. The semiconductor device of claim 1, wherein the data storage structure includes a first electrode in contact with the cell pad portion, a second electrode on the first electrode, and a dielectric layer between the first electrode and the second electrode.

11. The semiconductor device of claim 1, wherein the cell gate is at a lower level than the peripheral gate and the bit line, and
wherein at least a portion of the bit line is at the same level as at least a portion of the peripheral gate.

12. The semiconductor device of claim 1, wherein the bit line is at a lower level than the cell gate, and
wherein the second cell source/drain region is at a higher level than the first cell source/drain region.

13. A semiconductor device comprising:
a first cell source/drain region, a second cell source/drain region, and a cell gate including a cell transistor;
a first peripheral source/drain region, a second peripheral source/drain region, and a peripheral gate including a peripheral transistor;
a bit line electrically connected to the first cell source/drain region;
a cell conductive structure electrically connected to the second cell source/drain region;
a peripheral conductive structure electrically connected to the first peripheral source/drain region; and
a data storage structure electrically connected to the cell conductive structure,
wherein the cell conductive structure includes:
a cell contact portion on the second cell source/drain region; and
a cell pad portion on the cell contact portion,
wherein the peripheral conductive structure includes:
a peripheral contact portion on the first peripheral source/drain region; and
a peripheral wiring portion on the peripheral contact portion,
wherein, in a plan view, the cell pad portion includes:
a first side and a second side opposing each other in a first direction;
a third side and a fourth side opposing each other in a second direction different from the first direction;
a first rounded corner where a first side and the fourth side meet;
a second rounded corner where a first side and the third side meet;
a third rounded corner where a second side and the third side meet; and
a fourth rounded corner where a second side and the fourth side meet,
wherein the peripheral wiring portion has a line shape extending in a third direction, and
wherein the third direction is different from the first direction and the second direction.

14. The semiconductor device of claim 13, wherein a distance between the first rounded corner and the third rounded corner is greater than a distance between the second rounded corner and fourth rounded corner.

15. A semiconductor device comprising:
a first cell source/drain region, a second cell source/drain region, and a cell gate including a cell transistor;
a bit line electrically connected to the first cell source/drain region;
a cell conductive structure electrically connected to the second cell source/drain region; and
a data storage structure electrically connected to the cell conductive structure,
wherein the cell conductive structure includes:
a cell contact plug on the second cell source/drain region; and
a cell pad pattern on the cell contact plug,
wherein, in a plan view, the cell pad pattern includes:
a first side and a second side opposing each other in a first direction;
a third side and a fourth side opposing each other in a second direction different from the first direction;
a first rounded corner where a first side and the fourth side meet;
a second rounded corner where a first side and the third side meet;
a third rounded corner where a second side and the third side meet; and
a fourth rounded corner where a second side and the fourth side meet,
wherein the first rounded corner and the third rounded corner oppose each other in a third direction,
wherein the second rounded corner and the fourth rounded corner oppose each other in a fourth direction perpendicular to the third direction, and
wherein the bit line has a line shape extending in the third direction.

16. The semiconductor device of claim 15, wherein the cell gate has a line shape extending in the fourth direction.

17. The semiconductor device of claim 15, wherein a distance between the first rounded corner and the third rounded corner is different from a distance between the second rounded corner and fourth rounded corner.

18. The semiconductor device of claim 15, wherein a distance between the first rounded corner and the third rounded corner is greater than a distance between the second rounded corner and fourth rounded corner.

19. The semiconductor device of claim 15, wherein the cell gate is at a lower level than a peripheral gate and the bit line, and
wherein at least a portion of the bit line is at the same level as at least a portion of the peripheral gate.

20. The semiconductor device of claim 15, wherein the bit line is at a lower level than the cell gate, and
wherein the second cell source/drain region is at a higher level than the first cell source/drain region.
